(19) United States
(12) Patent Application Publication
(10) Pub. No.: US 2025/0132255 A1
(43) Pub. Date: Apr. 24, 2025

(54) REDUCING CURRENT-RESISTOR (IR) DROPS USING FEOL AND MEOL STRUCTURES

(71) Applicant: QUALCOMM Incorporated, San Diego, CA (US)

(72) Inventors: Channappa DESAI, Haveri (IN); Sunil SHARMA, Bangalore (IN); Rahul BIRADAR, Kalaburgi (IN); Ramakoti NIMMAKAYALA, Bangalore (IN); Prasanth KONDALAMPATTI SEKAR, Salem (IN); Anne SRIKANTH, Bangalore (IN)

(21) Appl. No.: 18/492,613

(22) Filed: Oct. 23, 2023

(51) Int. Cl. H01L 23/528; H01L 23/522

(52) U.S. Cl. CPC H01L 23/5286; H01L 23/5226

(57) ABSTRACT

Aspects of the present disclosure provide a filler cell that may be placed next to the active cell to reduce a current-resistor (IR) drop for the active cell. The filler cell includes an active dummy device coupled to a source of a transistor in the active cell and a rail (e.g., a ground rail or a voltage supply rail). The filler cell provides the active cell with at least one additional current path between the source of the transistor and the rail through the active dummy device, which reduces the IR drop between the source of the transistor and the rail.

### BACKGROUND

### Field

Aspects of the present disclosure relate generally to reducing IR drops on a chip, and more particularly, to reducing IR drops on the chip using front-end-of-line (FEOL) and middle-end-of-line (MEOL) structures.

### Background

A chip (i.e., silicon die) may include a large number of active devices (e.g., transistors). To receive power, each active device may be coupled to a supply voltage and a ground through conductive paths formed from multiple layers on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

An aspect relates to a chip. The chip includes a first cell including a first diffusion region extending in a first direction, and first gates formed over the first diffusion region, wherein each of the first gates is elongated and extends in a second direction perpendicular to the first direction. The chip also includes a second cell including a second diffusion region extending in the first direction, and second gates formed over the second diffusion region, wherein each of the second gates is elongated and extends in the second direction. The chip also includes a first contact extending in the second direction over the first diffusion region and the second diffusion region, wherein the first cell includes a first portion of the first contact and the second cell includes a second portion of the first contact. The chip also includes a first via disposed on the first contact between the first diffusion region and the second diffusion region, and a rail extending in the first direction over the first via, wherein the first via couples the first contact to the rail.

### BRIEF DESCRIPTION OF THE DRAWINGS

FIG. 1 shows a side view of an example of a chip including multiple layers according to certain aspects of the present disclosure.

FIG. 2 shows an example of an active cell and a filler cell according to certain aspects of the present disclosure.

FIG. 3A shows an exemplary layout including a first oxide diffusion (OD) region in the active cell, a second OD region in the filler cell, and gates extending over the first and second OD regions according to certain aspects of the present disclosure.

FIG. 3B shows an example in which the gates of FIG. 3A are cut to form gates in the active cell and gates in the filler cell according to certain aspects of the present disclosure.

FIG. 3C shows an example of contacts formed over the first and second OD regions according to certain aspects of the present disclosure.

FIG. 3D shows an example in which the contacts of FIG. 3C are cut to form contacts in the active cell and contacts in the filler cell according to certain aspects of the present disclosure.

FIG. 3E shows an example of vias disposed on the gates and the contacts in the active cell according to certain aspects of the present disclosure.

FIG. 3F shows an example of a metal rail coupled to at least one of the contacts in the active cell according to certain aspects of the present disclosure.

FIG. 4 shows an example of an active cell and a filler cell for reducing IR drop according to certain aspects of the present disclosure.

FIG. 5A shows an example of contacts formed over a first OD region in the active cell and a second OD region in the filler cell of FIG. 4 according to certain aspects of the present disclosure.

FIG. 5B shows an example in which the contacts of FIG. 5A are cut to form contacts in the active cell and contacts in the filler cell according to certain aspects of the present disclosure.

FIG. 5C shows an example of vias disposed on the gates and the contacts in the active cell and vias disposed on the gates and the contacts in the filler cell according to certain aspects of the present disclosure.

FIG. 5D shows an example of metal paths and a metal rail formed over the vias of FIG. 5C from a first metal layer the according to certain aspects of the present disclosure.

FIG. 5E shows an example of vias disposed on the metal paths and the rail of FIG. 5D according to certain aspects of the present disclosure.

FIG. 5F shows an example of metal paths formed over the vias of FIG. 5E from a second metal layer above the first metal layer the according to certain aspects of the present disclosure.

FIG. 6 is a block diagram illustrating a computer system according to certain aspects of the present disclosure.

FIG. 7 is a block diagram illustrating an example of a system in which aspects of the present disclosure may be used.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

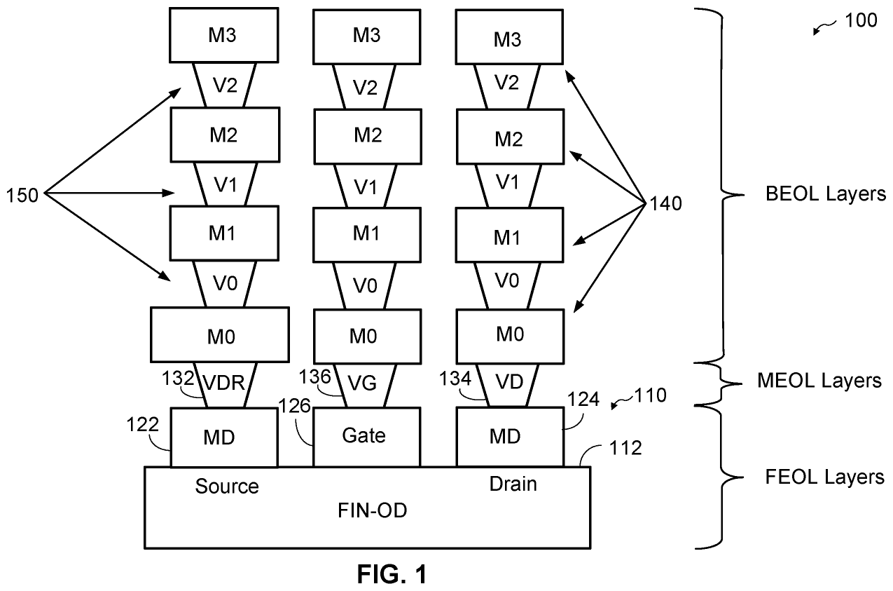

FIG. 1 shows a side view of an example of a chip 100 (e.g., a silicon die) including multiple layers according to certain aspects. During fabrication, the layers may be sequentially formed or deposited on a substrate (e.g., p substrate) of the chip 100 and patterned to form various structures on the chip 100. It is to be appreciated that the chip 100 is not limited to the exemplary layers shown in FIG. 1.

In this example, the chip 100 includes a front-end-of-line (FEOL), a back-end-of-line (BEOL), and a middle-end-of-line (MEOL). The MEOL may also be referred to as the middle-of-line (MOL) or another term. The FEOL includes active devices (e.g., transistors) formed on the chip 100. For example, the FEOL may include the oxide diffusion (OD) regions and the gates of the active devices. The FEOL may include a large number of active devices (e.g., transistors) integrated on the chip 100. In this regard, FIG. 1 shows an example of a transistor 110 in the FEOL. Although one transistor 110 is shown in FIG. 1 for simplicity, it is to be appreciated that the FEOL includes many transistors.

In the example shown in FIG. 1, the transistor 110 includes an OD region 112 and a gate 126 in the FEOL, in which the gate 126 is formed over the OD region 112. The OD region 112 may also be referred to as a diffusion region, an active region, a diffusion, or another term. The gate 126 may include polysilicon (also referred to as poly), a gate metal, and/or another gate material. A portion of the OD region 112 under the gate 126 provides the channel of the transistor 110. In the example shown in FIG. 1, a portion of the OD region 112 to the right of the gate 126 provides the drain of the transistor 110 and a portion of the OD region to the left of the gate 126 provides the source of the transistor 110, or vice versa.

The FEOL may also include a contact 122 formed on the source and a contact 124 formed on the drain. The contact 122 and the contact 124 may be formed (i.e., patterned) from a contact layer using, for example, lithographic and etching processes. The contact layer may be referred to as metal-to-diffusion (MD), contact active (CA), or another term. In the FIG. 1, the contact layer is labeled “MD”.

The BEOL includes a stack of metal layers 140. The metal layers 140 are patterned (e.g., using lithography and etching) to provide metal routing for the transistor 110 and other active devices (e.g., transistors) on the chip 100. The metal routing may be used, for example, to interconnect active devices on the chip 100. The metal layers 140 may also be patterned to form a power distribution network including supply rails (also referred to as power rails or power buses) for distributing power to the active devices on the chip 100.

In the example in FIG. 1, the bottom-most metal layer in the BEOL is referred to as metal layer M0, the metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers are shown in FIG. 1 for ease of illustration, it is to be appreciated that the BEOL may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0.

The BEOL also includes vias 150 that provide electrical coupling between the metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3.

The MEOL is between the FEOL and the BEOL, and provides structures (e.g., vias) for electrically coupling the active devices in the FEOL to the BEOL (e.g., metal layer M0 of the BEOL). In the example in FIG. 1, the MEOL includes a via 134 (labeled “VD”) for coupling the contact 124 (e.g., drain contact) to metal routing formed in metal layer M0, a gate via 136 (labeled “VG”) for coupling the gate 126 to metal routing formed in metal layer M0, and a via 132 (labeled “VDR”) for coupling the contact 122 (e.g., source contact) to a supply rail or a ground rail formed in metal layer M0. However, it is to be appreciated that the present disclosure is not limited to this example.

Although one gate 126 is shown in FIG. 1, it is to be appreciated that the transistor 110 may include multiple gates formed over the OD region 112, in which the multiple gates are arranged in parallel and coupled to one another (e.g., through metal layer M0). A transistor with multiple gates may be referred to as multi-finger transistor or another term.

As discussed above, the chip 100 includes many active devices (e.g., transistors). To receive power, each of the active devices may be coupled to a supply voltage and a ground through conductive paths in the chip 100, in which the conductive paths may include one or more contacts formed (i.e., patterned) from the contact layer MD, one or more vias (e.g., VDR and/or VD), and one or more rails formed (i.e., patterned) from one or more of the metal layers 140. In advanced process technologies, one or more of the conductive paths may have a high resistance that increases the IR drop across the one or more conductive paths, which reduces the operating voltage of the active device. The reduction in the operating voltage of the active device degrades the performance (e.g., speed) of the active device, which may cause a circuit that includes the active device to fail to meet performance requirements for the circuit. Accordingly, techniques for reducing IR drops are desirable.

In certain aspects, active devices (e.g., transistors) on the chip 100 may be grouped into cells. Each of these cells may include one or more of the active devices arranged to provide a circuit (e.g., a driver, a logic circuit including one or more logic gates, or another circuit). The layouts of the cells may be specified by a cell library, which stores the layout of each one of various cells that can be placed on the chip 100. The chip 100 may include multiple instances of a particular cell in the cell library. The cell library may also store the layouts of one or more filler cells, one or more decap cells, one of more endcap cells, etc. A filler cell may include one or more dummy devices, as discussed further below.

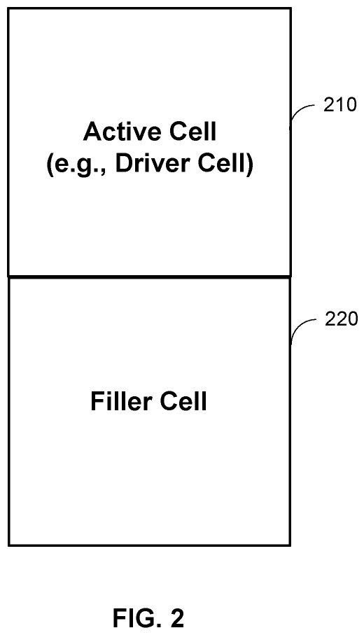

FIG. 2 is a block diagram showing an example of an active cell 210 and a filler cell 220 that may be placed on the chip 100, in which the filler cell 220 is adjacent to the active cell 210. The active cell 210 includes one or more active devices (e.g., one or more instances of the transistor 110) that are arranged to provide a circuit (e.g., a driver, a logic circuit, or another circuit) on the chip 100. In one example, the active cell 210 is a driver cell including active devices that are arranged to provide a driver configured to drive a signal path (e.g., global data path) with a signal. The driver may include an n-type metal-oxide-semiconductor (NMOS) transistor and a p-type metal-oxide-semiconductor (PMOS) transistor arranged to form a complementary inverter. However, it is to be appreciated that the driver is not limited to this example.

The filler cell 220 includes one or more non-active dummy devices to help maintain pattern uniformity on the chip. The one or more non-active dummy devices may include floating gates and floating source/drain contacts, as discussed further below. The filler cell 220 may be placed, for example, in an area of the chip 100 reserved for implementing a potential future engineering change order (ECO).

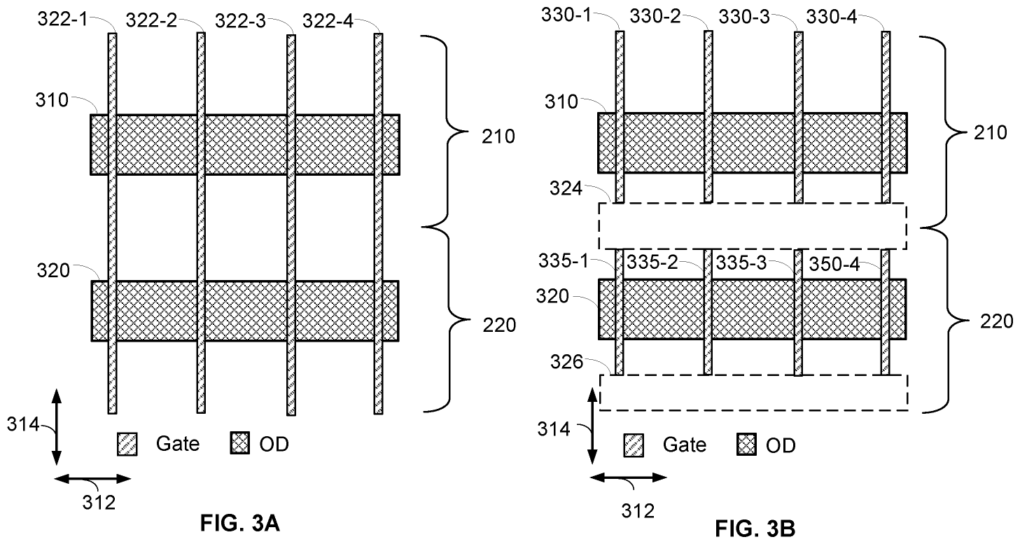

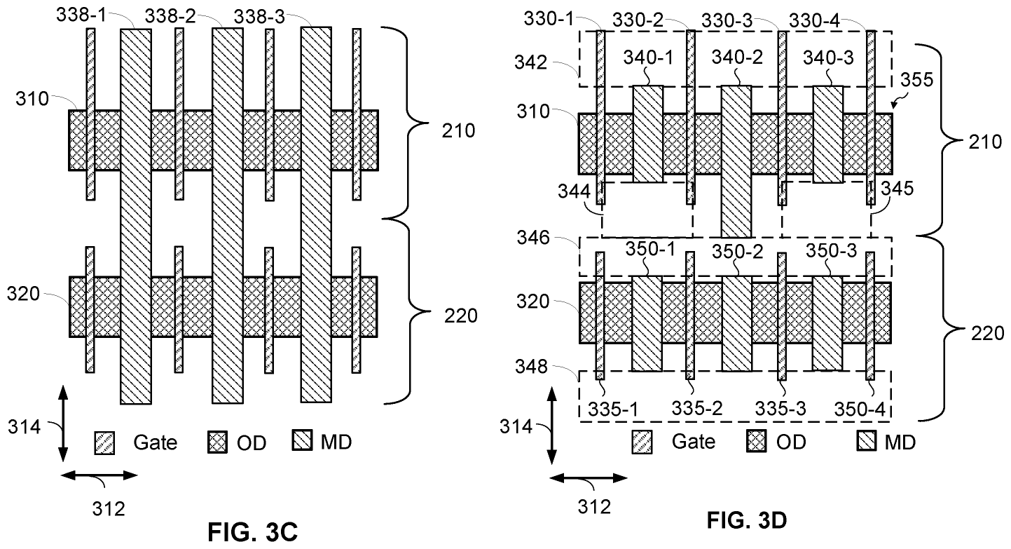

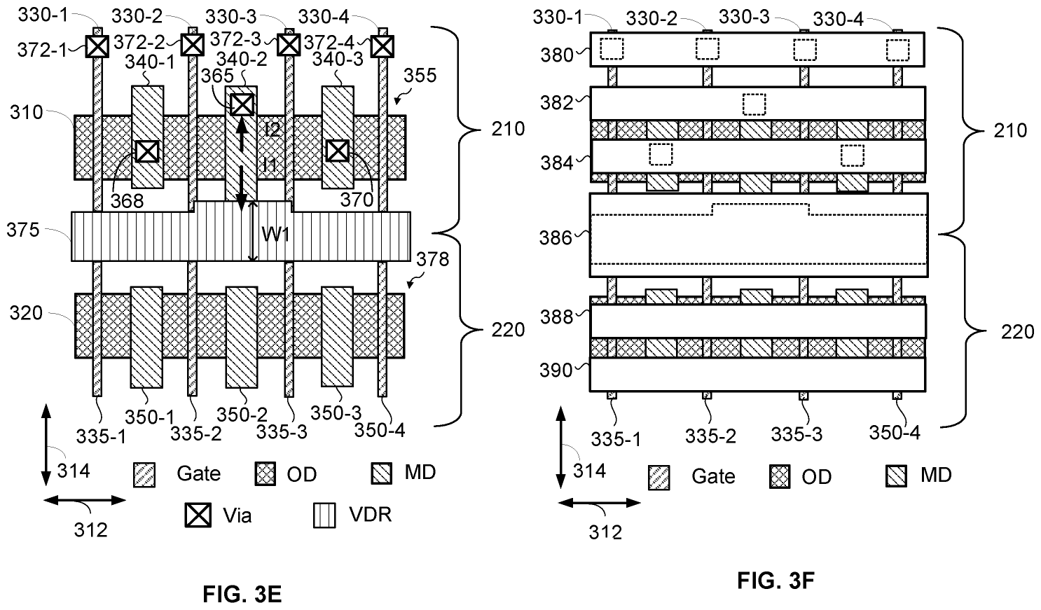

FIGS. 3A to 3F show top views of various layers of an exemplary layout of the active cell 210 (e.g., driver cell) and the filler cell 220 according to certain aspects. As shown in FIG. 3A, the active cell 210 includes a first OD region 310 extending in a first direction 312 (e.g., horizontal direction), and the filler cell 220 includes a second OD region 320 extending in the first direction 312. For a FinFet process, each of the OD regions 310 and 320 may include fins extending in the first direction 312 (e.g., horizontal direction).

FIG. 3A also shows an example of gates 322-1 to 322-4 (e.g., poly gates) formed over the first OD region 310 and the second OD region 320. The gates 322-1 to 322-4 are arranged in parallel, and may be evenly spaced apart in the first direction 312. Each of the gates 322-1 to 322-4 is elongated and extends in a second direction 314 (e.g., vertical direction) that is perpendicular to the first direction 312 (e.g., horizontal direction). The gates 322-1 to 322-4 may include polysilicon or another type of gate material.

In FIG. 3B, the gates 322-1 to 322-4 shown in FIG. 3A are cut 324 and 326 to form gates 330-1 to 330-4 in the active cell 210 and gates 335-1 to 335-4 in the filler cell 220. The gates 330-1 to 330-4 extend in the second direction 314 (e.g., vertical direction) over the first OD region 310, and the gates 335-1 to 335-4 extend in second direction 314 (e.g., vertical direction) over the second OD region 320. The gates 330-1 to 330-4 and the gates 335-1 to 335-4 are separated by the cut 324 (e.g., poly cut), as shown in FIG. 3B. The cuts can be performing using lithographic and etching processes. For the example of poly gates, the cuts may also be referred to as cut poly (CP).

FIG. 3C also shows an example of contacts 338-1 to 338-3 formed from contact layer MD (e.g., using lithographic and etching processes). Each of the contacts 338-1 to 338-3 is elongated and extends in the second direction 314 (e.g., vertical direction) over the first OD region 310 and the second OD region 320.

In FIG. 3D, the contacts 338-1 to 338-3 shown in FIG. 3C are cut 342, 344, 345, 346, and 348 to form contacts 340-1 to 340-3 in the active cell 210 and contacts 350-1 to 350-3 in the filler cell 220. The contacts 340-1 to 340-3 extend in the second direction 314 (e.g., vertical direction) over the first OD region 310, and the contacts 350-1 to 350-3 extend in second direction 314 (e.g., vertical direction) over the second OD region 320. The contacts 340-1 to 340-3 and the contacts 350-1 to 350-4 are separated by the cut 346, as shown in FIG. 3D. The cuts 344 and 345 may merge with cut 346 to form a single cut.

In certain aspects, the first OD region 310 and the gates 330-1 to 330-4 in the active cell 210 form a transistor 355 (e.g., an NMOS transistor) in which the contacts 340-1 and 340-3 provide drain contacts for the transistor 355 and the contact 340-2 provides a source contact for the transistor 355. In this example, the contact 340-2 (i.e., source contact) extends farther below the first OD region 310 in the second direction 314 (e.g., vertical direction) than the contacts 340-1 and 340-3 (i.e., drain contacts).

FIG. 3E shows an example of gate vias 372-1 to 372-4 (VG vias) disposed on the gates 330-1 to 330-4, a via 365 (VD via) disposed on the contact 340-2 (i.e., source contact), and vias 368 and 370 (VD vias) disposed on the contacts 340-1 and 340-3 (i.e., drain contacts). The gate vias 372-1 and 372-4 are shifted with respect to the via 365 in the second direction 314 (e.g., vertical direction), and the vias 368 and 370 are shifted with respect to the via 365 in the second direction 314 (e.g., vertical direction). FIG. 3E also shows an example of a rail via 375 (VDR via) disposed on a portion of the contact 340-2 that extends below the contacts 340-1 and 340-3 in the second direction (e.g., vertical direction). In this example, the portion of the rail via 375 disposed on the contact 340-2 has a width of W1 in the second direction 314. As discussed further below, the rail via 375 is used to couple the contact 340-2 (i.e., source contact) to a rail formed in metal layer M0 of the BEOL.

In the example in FIG. 3E, there are no vias disposed on the gates 335-1 to 335-4 and the contacts 350-1 to 350-3 in the filler cell 220. As a result, the gates 335-1 to 335-4 and the contacts 350-1 to 350-3 in the filler cell 220 are left floating (i.e., not coupled to a rail or a signal path). Consequently, the second OD region 320 and the gates 335-1 to 335-4 form a non-active dummy device 378.

FIG. 3F shows an example of metal paths 380, 382, 384, 388, and 390 and a rail 386 formed (i.e., patterned) from metal layer M0. The vias in FIG. 3E are shown in dotted lines in FIG. 3F to indicate that the vias are below the metal paths 380, 382, 384, 388, and 390 and the rail 386. In the example in FIG. 3F, each of the metal paths 380, 382, 384, 388, and 390 is a metal line extending in the first direction 312 (e.g., horizontal direction). However, it is to be appreciated that the present disclosure is not limited to this example.

The rail 386 may be a voltage supply rail or a ground rail. For the example where the transistor 355 is an NMOS transistor, the rail 386 may be a ground rail (also referred to as a Vss rail or another term). For the example where the transistor 355 is a PMOS transistor, the rail 386 may be a voltage supply rail (also referred to as a Vdd rail or another term).

Each of metal paths 380, 382, 384, 388, and 390 extends in the first direction 312 (e.g., horizontal direction). The metal paths 380, 382, 384, 388, and 390 are spaced apart from one another in the second direction 314 (e.g., vertical direction). The metal path 380 extends over the gate vias 372-1 to 372-4 and is coupled to the gates 330-1 to 330-4 by the gate vias 372-1 to 372-4. The metal path 382 extends over the via 365 and is coupled to the contact 340-2 (i.e., source contact) by the via 365. The metal path 384 extends over the vias 368 and 370, and is coupled to the contacts 340-1 and 340-3 by the vias 368 and 370. The metal paths 388 and 390 extend over the non-active dummy device 378 but are not coupled to the non-active dummy device 378 since there are no vias coupling the metal paths 388 and 390 to the non-active dummy device 378.

For the example where the active cell 210 is a driver cell, the metal path 380 coupled to the gates 330-1 to 330-3 may be provide an input of the driver cell and the metal path 384 coupled to the contacts 340-1 and 340-3 (i.e., drain contacts) may provide an output of the driver cell. However, it is to be appreciated that the present disclosure is not limited to this example.

The rail 386 extends over the rail via 375 and is coupled to the contact 340-2 (i.e., source contact) by the rail via 375. Thus, the rail 386 (e.g., ground rail or voltage supply rail) is coupled to the source of the transistor 355 through a first path (labeled “I1” in FIG. 3E) including the portion of the contact 340-2 that extends to the rail via 375 and the rail via 375.

The metal path 382 is also coupled to the source of the transistor 355 through via 365. In certain aspects, the metal path 382 is coupled to the rail 386 through a metal path (not shown) in metal layer M1 extending in the second direction 314 (e.g., vertical direction) between the metal path 382 and the rail 386. This provides a second path (labeled “I2” in FIG. 3E) from the source of the transistor 355 to the rail 386 through the metal path 382 and the metal path (not shown) in metal layer M1 coupling the metal path 382 to the rail 386.

Thus, in this example, there are two parallel paths from the source of the transistor 355 to the rail 386 (i.e., the first path labeled “I1” and the second path labeled “I2”). In this example, the IR drop between the source of the transistor 355 and the rail 386 depends on the resistance of the first path and the second path. In some cases, the IR drop may exceed a maximum IR drop satisfying a design requirement for the active cell 210. For the example where the active cell 210 is a driver cell, a relatively large current may flow between the source and the rail 386 during operation, which increases the IR drop between the source and the rail 386, making it more difficult to meet the design requirement for the IR drop using the layout shown in FIGS. 3A to 3F.

The filler cell 220 does not help reduce the IR drop between the source and the rail 386. This is because the non-active dummy device 378 in the filler cell 220 is not coupled to the source of the transistor 355 due to the cut 346 in FIG. 3D, and therefore does not provide a current path between the source and the rail 386.

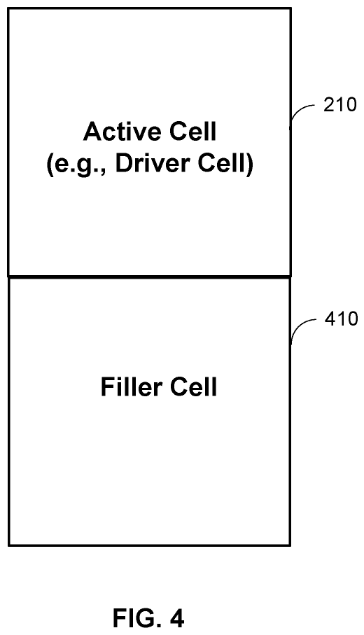

To address the above, aspects of the present disclosure provide a filler cell 410 (shown in FIG. 4) that may be placed next to the active cell 210 to reduce the IR drop discussed above. The filler cell 410 includes an active dummy device (not shown in FIG. 4) coupled to the source of the transistor in the active cell 210 and the rail (e.g., ground rail or voltage supply rail). The filler cell 410 provides the active cell 210 with at least one additional current path between the source of the transistor and the rail through the active dummy device, which reduces the IR drop between the source of the transistor and the rail. The above features and other features of the filler cell 410 are discussed further below.

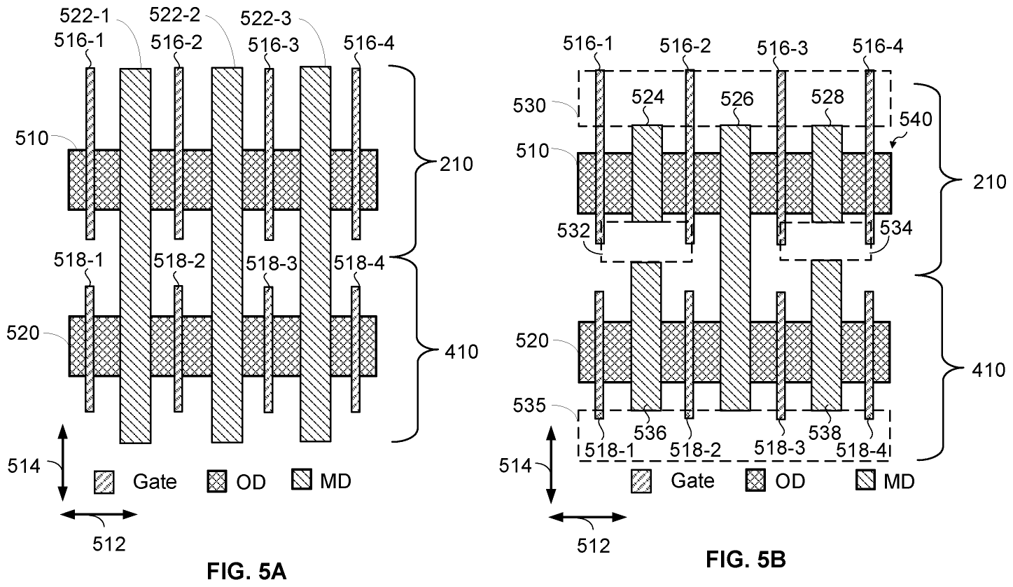

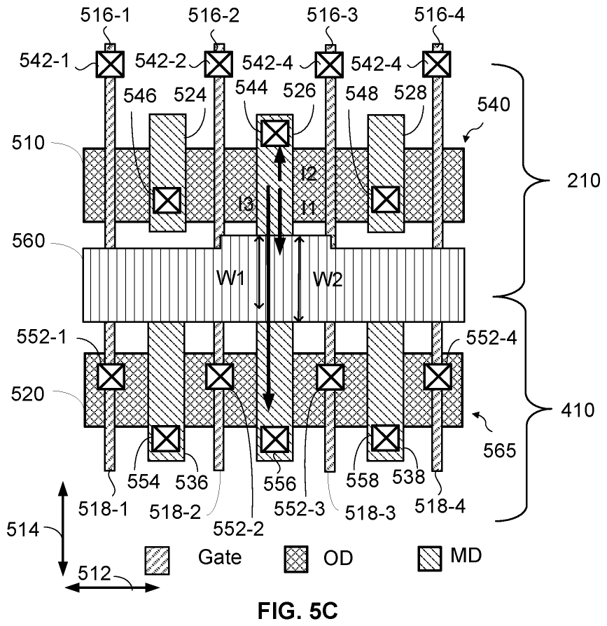

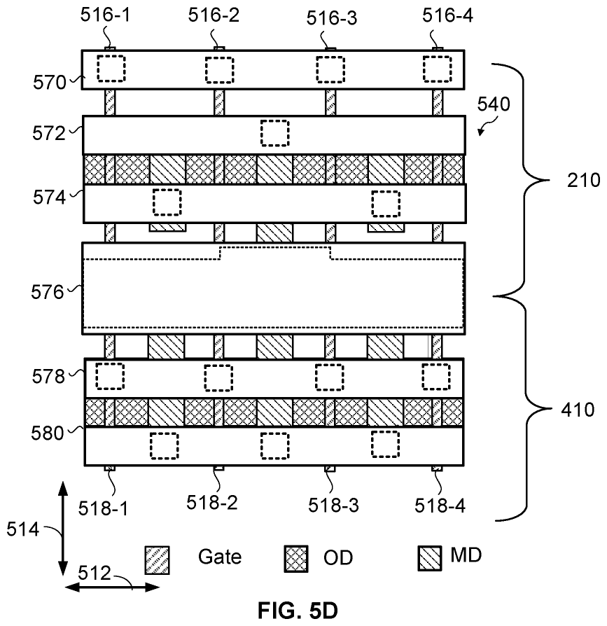

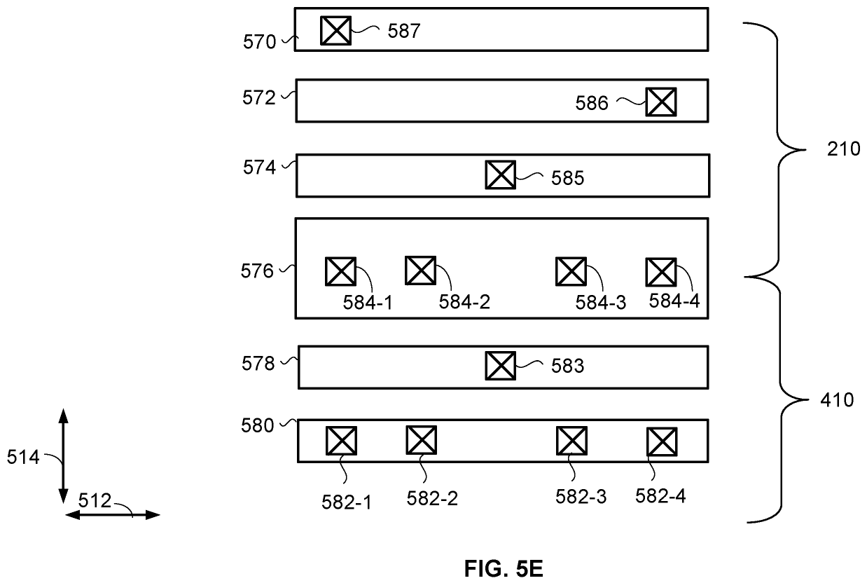

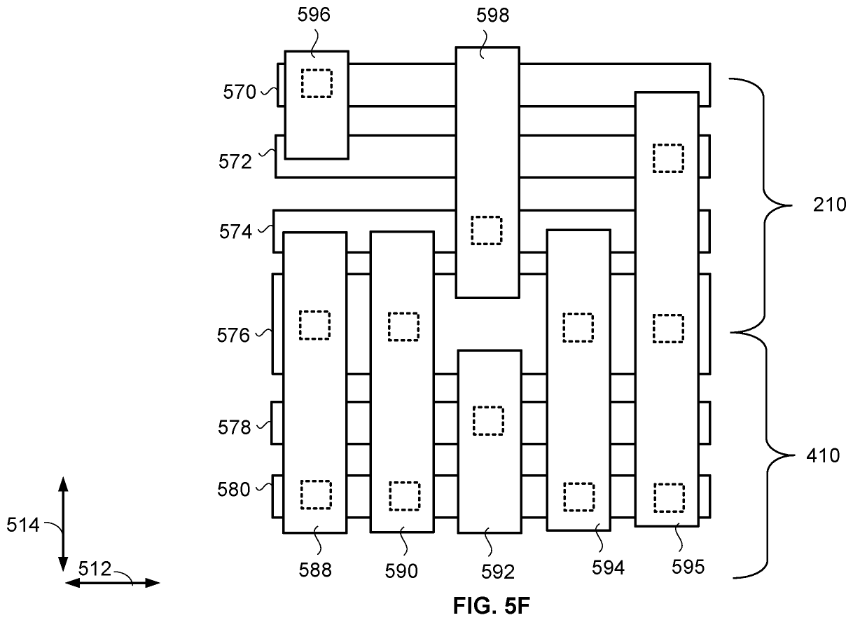

FIGS. 5A to 5F show top views of various layers of an exemplary layout of the active cell 210 (e.g., driver cell) and the filler cell 410 according to certain aspects. As shown in FIG. 5A, the active cell 210 includes a first OD region 510 extending in a first direction 512 (e.g., horizontal direction), and the filler cell 410 includes a second OD region 520 extending in the first direction 512. For a FinFet process, each of the OD regions 510 and 520 may include fins extending in the first direction 512 (e.g., horizontal direction).

In FIG. 5A, the active cell 210 includes gates 516-1 to 516-4 and the filler cell 410 includes gates 518-1 to 518-4. The gates 516-1 to 516-4 and the gates 518-1 to 518-4 may be formed by cutting gates that extend across the cells in a manner similar to the gate cut (i.e., poly cut) shown in FIG. 3B. The gates 516-1 to 516-4 may also be referred to as first gates, and the gates 518-1 to 518-4 may also be referred to as second gates. The gates 516-1 to 516-4 and 518-1 and 518-4 may include polysilicon, gate metal, or another types of gate material.

The gates 516-1 to 516-4 are arranged in parallel, and may be evenly spaced apart in the first direction 512. Each of the gates 516-1 to 516-4 is elongated and extends over the first OD region 510 in a second direction 514 (e.g., vertical direction) that is perpendicular to the first direction 312 (e.g., horizontal direction). The gates 518-1 to 518-4 are arranged in parallel, and may be evenly spaced apart in the first direction 512. Each of the gates 518-1 to 518-4 is elongated and extends over the second OD region 520 in the second direction 514 (e.g., vertical direction).

FIG. 5A also shows an example of contacts 522-1 to 522-3 formed from contact layer MD (e.g., using lithographic and etching processes). Each of the contacts 522-1 to 522-3 is elongated and extends in the second direction 314 (e.g., vertical direction) over the first OD region 510 and the second OD region 520.

In FIG. 5B, the contacts 522-1 to 522-3 shown in FIG. 5A are cut 530, 532, 534, and 535 to form a contact 524, a contact 526, a contact 528, a contact 536, and a contact 538. The contact 524, the contact 526, and the contact 528 extend in the second direction 514 (e.g., vertical direction) over the first OD region 510.

In this example, the first OD region 310 and the gates 516-1 to 516-4 in the active cell 210 form a transistor 540 (e.g., an NMOS transistor) in which the contact 524 and the contact 528 provide drain contacts for the transistor 540, and the contact 526 provides a source contact for the transistor 540. In the example in FIG. 5B, the gate 516-2 is between the contact 524 (i.e., drain contact) and the contact 526 (i.e., source contact), and the gate 516-3 is between the contact 526 (i.e., source contact) and the contact 528 (i.e., drain contact).

In this example, the cut 346 shown in FIG. 3D is removed. The removal of the cut 346 allows the contact 526 to extend downward in the second direction 514 (i.e., vertical direction) into the filler cell 410. In the example in FIG. 5B, the contact 526 extends over the second OD region 520 in the filler cell 410. Thus, the contact 526 (which is contiguous in the contact layer MD) extends over both the first OD region 510 and the second OD region 520. In this example, the active cell 210 includes a first portion of the contact 526 (e.g., source contact) and the filler cell 410 includes a second portion of the contact 526.

The contact 536 and the contact 538 extend in the second direction over the second OD region 520. The cut 532 separates the contact 524 and the contact 536, and the cut 534 separates the contact 528 and the contact 538. The gate 518-2 is between the contact 536 and the contact 526, and the gate 518-3 is between the contact 526 and the contact 538.

The second OD region 520 and the gates 518-1 to 518-4 in the filler cell 410 form a dummy device 565 (shown in FIG. 5C) in which the contact 536, the contact 526, and the contact 538 provide contacts for the dummy device 565. As discussed further below, the dummy device 565 is an active dummy device with the contacts 536, 526, and 538 and the gates 518-1 to 518-4 of the dummy device 565 coupled to metal paths in metal layer M1. In contrast, the dummy device 378 in the filler cell 220 is non-active with the contacts 350-1 to 350-4 and the gates 335-1 to 335-4 of the dummy device 378 left floating.

FIG. 5C shows an example of gate vias 542-1 to 542-4 (VG vias) disposed on the gates 516-1 to 516-4, a via 544 (VD via) disposed on the contact 526 (i.e., source contact), and vias 546 and 548 (VD vias) disposed on the contacts 524 and 528, respectively. The gate vias 542-1 to 542-4 are shifted with respect to the via 544 in the second direction 514 (e.g., vertical direction), and the vias 546 and 548 are shifted with respect to the via 544 in the second direction 514 (e.g., vertical direction). FIG. 5C also shows an example of a rail via 560 (VDR via) disposed on a portion of the contact 526 between the first OD region 510 and the second OD region 520. In this example, the portion of the rail via 560 (VDR via) disposed on the contact 526 has a width W2 in the second direction 514. In this example, the removal of the cut 346 allows the width W2 of the rail via 560 to be wider than the width W1 of the rail via 375 in FIG. 3E. Once the cut 346 is removed, VDR widening is feasible (in compliance with a design rule check (DRC) for the process used to fabricate the chip 100). For comparison, the width W1 of the rail via 375 is shown in FIG. 5C. The wider width of the rail via 560 has the benefit of reducing the resistance of the rail via 560, which reduces the IR drop in the rail via 560.

FIG. 5C also shows an example of gate vias 552-1 to 552-4 (VG vias) disposed on the gates 518-1 to 518-4, a via 554 (VD via) disposed on the contact 536, a via 556 (VD via) disposed on the contact 526, and a via 558 disposed on the contact 538. The vias 554, 556, and 558 are aligned in the second direction 514 (e.g., vertical direction). The gate vias 552-1 to 552-4 are shifted with respect to the vias 554, 556, and 558 in the second direction 314 (e.g., vertical direction). Thus, in this example, the chip 100 includes vias disposed on the gates and contacts in the filler cell 410 in contrast to the filler cell 220 in FIG. 3E, in which the gates and contacts are left floating. In this example, the via 544 is disposed on the first portion of the contact 526 in the active cell 210, and the via 556 is disposed on the second portion of the contact 526 in the filler cell 410.

FIG. 5D shows an example of metal paths 570, 572, 574, 578, and 580 and a rail 576 formed (i.e., patterned) from metal layer M0. The rail 576 may be a voltage supply rail or a ground rail. For the example where the transistor 540 is an NMOS transistor, the rail 576 may be a ground rail (also referred to as a Vss rail or another term). For the example where the transistor 540 is a PMOS transistor, the rail 576 may be a voltage supply rail (also referred to as a Vdd rail or another term). The rail 576 and each of metal paths 570, 572, 574, 578, and 580 is elongated and extends in the first direction 512 (e.g., horizontal direction). The rail 576 and the metal paths 572, 574, 578, and 580 are spaced apart from one another in the second direction 514 (e.g., vertical direction). In the example in FIG. 5D, each of the metal paths 570, 572, 574, 578, and 580 is a metal line extending in the first direction 512 (e.g., horizontal direction). However, it is to be appreciated that the present disclosure is not limited to this example. It is to be appreciated that the rail 576 may extend over multiple cells (not shown) in a row.

The metal path 570 extends over the gate vias 542-1 to 542-4 and is coupled to the gates 516-1 to 516-4 by the gate vias 542-1 to 542-4. The metal path 572 extends over the via 544 and is coupled to the contact 526 (i.e., source contact) by the via 544. The metal path 574 extends over the vias 546 and 548, and is coupled to the contacts 524 and 528 by the vias 546 and 548.

For the example where the active cell 210 is a driver cell, the metal path 570 coupled to the gates 516-1 to 516-4 may be provide an input of the driver cell and the metal path 574 coupled to the contacts 524 and 528 (i.e., drain contacts) may provide an output of the driver cell. However, it is to be appreciated that the present disclosure is not limited to this example.

The rail 576 extends over the rail via 560 and is coupled to the contact 526 (i.e., source contact) by the rail via 560. Thus, the source of the transistor 540 is coupled to the rail 576 (e.g., ground rail) through a first path (labeled “I1” in FIG. 5C) including the portion of the contact 526 that extends to the rail via 560 and the rail via 560.

The source of the transistor 540 is also coupled to the metal path 572 through a second path (labeled “I2” in FIG. 5C) including the portion of the contact 526 that extends to the via 544 and the via 544. As discussed further below with reference to FIG. 5F, the first path is coupled to the rail 576 through metal layer M1.

The metal path 578 extends over the gate vias 552-1 to 552-4 and is coupled to the gates 518-1 to 518-4 by the gate vias 552-1 to 552-4. The metal path 580 extends over the vias 554, 556, and 558 and is coupled to the contact 536, the contact 526 (i.e., source contact for the transistor 540), and the contact 538 by the vias 554, 556, and 558, respectively.

In this example, the source of the transistor 540 is also coupled to the metal path 580 through a third path (labeled “I3” in FIG. 5C) including the portion of the contact 526 that extends to the via 556 and the via 556. As discussed further below with reference to FIG. 5F, the first path, the second path, and the third path are coupled in parallel through metal layer M1. The third path provides the source of the transistor 540 with an additional path to the rail 576 in parallel with the first path and the second path, which reduces the IR drop between the source of the transistor 540 and the rail 576.

In certain aspects, the metal path 578 coupled to the gates 518-1 to 518-4 is coupled to a voltage that turns on the dummy device 565. For example, the dummy device 565 may be an n-type dummy device 565 in which the second OD region 520 is an n-type OD region. In this example, the dummy device 565 may be turned on by coupling the metal path 578 to a supply voltage (also referred to as Vdd). In another example, the dummy device 565 may be a p-type dummy device 565 in which the second OD region 520 is an p-type OD region. In this example, the dummy device 565 may be turned on by coupling the metal path 578 to a ground potential.

In these aspects, the turning on of the dummy device 565 turns on the channel under the gate 518-2 between the contact 526 and the contact 536, which provides an additional path between the contact 526 and the metal path 580 through the channel under the gate 518-2, the contact 536, and the via 554. The turning on of the dummy device 565 also turns on the channel under the gate 518-3 between the contact 526 and the contact 538, which provides an additional path between the contact 526 and the metal path 580 through the channel under the gate 518-3, the contact 538, and the via 558. These additional paths help reduce the IR drop between the contact 526 and the metal path 580.

FIG. 5E shows an example of vias 582-1 to 582-4 disposed on the metal path 580, a via 583 is disposed on the metal path 578, vias 584-1 to 584-4 disposed on the rail 576, a via 585 disposed on the metal path 574, a via 586 disposed on the metal path 572, and a via 587 disposed on the metal path 570. The vias (V0 vias) shown in FIG. 5E are disposed between metal layer M0 and metal layer M1.

FIG. 5F shows an example of metal paths 588, 590, 592, 594, 595, 596, and 598 formed (i.e., patterned) from metal layer M1, which is above metal layer M0 as shown in FIG. 1. Each of the metal paths 588, 590, 592, 594, 595, 596, and 598 is elongated and extends in the second direction 514 (e.g., vertical direction). The metal paths 588, 590, 592, 594, 595, 596, and 598 are spaced apart from one another in the first direction 512 (e.g., horizontal direction). The vias in FIG. 5E are shown in dotted lines in FIG. 5F to indicated that these vias are below the metal layer M1.

In the example in FIG. 5F, the metal path 588 extends over the vias 582-1 and 584-1 and is coupled between to the metal path 580 and the rail 576 by the vias 582-1 and 584-1. The metal path 590 extends over the vias 582-2 and 584-2 and is coupled between to the metal path 580 and the rail 576 by the vias 582-2 and 584-2. The metal path 594 extends over the vias 582-3 and 584-3 and is coupled between to the metal path 580 and the rail 576 by the vias 582-3 and 584-3. The metal path 595 extends over the vias 582-4 and 584-4 and is coupled between to the metal path 580 and the rail 576 by the vias 582-4 and 584-4. Thus, in this example, the metal path 580 is coupled to the rail 576 through the metal paths 588, 590, 594, and 595 in the metal layer M1 to provide the third path (labeled “I3” in FIG. 5C).

It is to be appreciated that one, two, or three of the metal paths 580, 590, 594, and 595 shown in the example in FIG. 5F may be omitted in some implementations. For example, a design rule check (DRC) for the process used to fabricate the chip 100 may not allow all of the metal paths 588, 590, 594, and 595, in which case one, two, or three of the metal paths 580, 590, 594, and 595 (e.g., metal lines) may be omitted to meet the DRC.

In the example in FIG. 5F, the metal path 595 also extend over the via 586 and is coupled between the metal path 572 and the rail 576 by the via 586 and the via 584-4. Thus, in this example, the metal path 572 is coupled to the rail 576 through the metal path 595 in the metal layer M1 to provide the second path (labeled “I2” in FIG. 5C).

In the example in FIG. 5F, the metal path 595 couples both the metal paths 580 and 572 to the rail 576. However, it is to be appreciated that the present disclosure is not limited to this example. For example, in other implementations, the metal path 572 may be coupled to the rail 576 by a separate metal path in the metal layer M1.

In the example in FIG. 5F, the metal path 592 extends over the via 583 and is coupled to the metal path 578 by the via 583. As discussed above, the metal path 578 is coupled to the gates 518-1 to 518-4 of the dummy device 565. The metal path 592 may be coupled to a voltage that turns on the dummy device 565. For example, the metal path 592 may be coupled to the supply voltage (also referred to as Vdd) for the example where the dummy device is an n-type dummy device 565, and ground potential for the example where the dummy device is a p-type dummy device 565.

In the example in FIG. 5F, the metal path 596 extends over the via 587 and is coupled to the metal path 570 by the via 587. As discussed above, the metal path 570 is coupled to the gates 516-1 to 516-4 of the transistor 540. For the example where the active cell 210 is a driver cell, the metal path 596 may route a signal to the input of the driver cell.

The metal path 598 extends over the via 585 and is coupled to the metal path 574 by the via 585. As discussed above, the metal path 574 is coupled to the drains of the transistor 540. For the example where the active cell 210 is a driver cell, the metal path 596 may be coupled to a signal path that is driven by the output of the driver cell.

It is to be appreciated that the present disclosure is not limited to the example shown in FIGS. 5A to 5F. For example, it is to be appreciated that the exemplary orientation of the active cell 210 and the filler cell 410 shown in FIGS. 5A to 5F may be flipped in the second direction 514 (e.g., the vertical direction). It is also to be appreciated that the active cell 210 and the filler cell 410 shown in FIG. 5A to 5F may be extended in the first direction 512 in which the exemplary layout of the active cell and the filler cell 410 shown in FIGS. 5A to 5F is repeated in the first direction 512.

It is also to be appreciated that the active cell 210 may include one or more additional transistors in addition to the transistor 540 shown in FIGS. 5A to 5F. For the example where the active cell 210 is a driver cell and the transistor 540 is an NMOS transistor, the active cell 210 may also include a PMOS transistor to complement the NMOS transistor. In this example, the NMOS transistor may be used for pulling down the output of the driver cell and the PMOS transistor may be used for pulling up the output of the driver cell based on the voltage at the input of the driver cell. Also, in this example, the rail 576 may be a ground rail (also referred to as Vss rail) and the dummy device 565 in the filler cell 410 may be an n-type dummy device. For the example where the active cell 210 is a driver cell and the transistor 540 is an PMOS transistor, the active cell 210 may also include an NMOS transistor to complement the PMOS transistor. In this example, the rail 576 may be a supply voltage rail (also referred to as Vdd rail) and the dummy device 565 in the filler cell 410 may be a p-type dummy device.

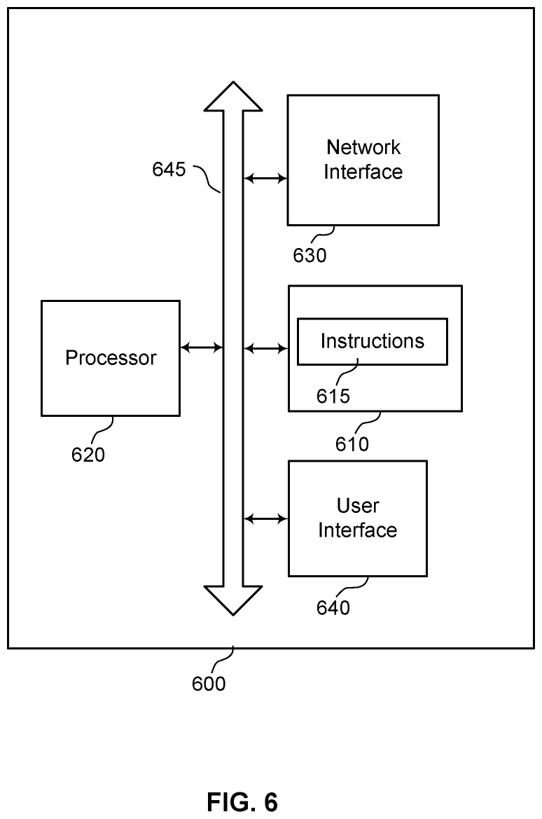

In certain aspects, the exemplary layouts discussed above may be determined using a computer system. In this regard, FIG. 6 illustrates a computer system 600 that may be used to determine layouts for the chip 100 according to certain aspects. The computer system 600 may include a processor 620, a memory 610, a network interface 630, and a user interface 640. These components may be in electronic communication via one or more buses 645.

The memory 610 may store instructions 615 that are executable by the processor 620 to cause the computer system 600 to perform one or more of the operations described herein. The processor 620 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof.

The memory 610 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof. The memory 610 may also store a cell library including files specifying layouts for various cells that may be placed on the chip 100 including layouts of the active cell 210 and the filler cell 410 (e.g., exemplary layouts shown in FIGS. 5A to 5F).

The network interface 630 is configured to interface the computer system 600 with one or more other devices. The user interface 640 may be configured to receive data from a user (e.g., via keypad, mouse, etc.) and provide the data to the processor 620. The user interface 640 may also be configured to output data from the processor 620 to the user (e.g., via a display, a speaker, etc.).

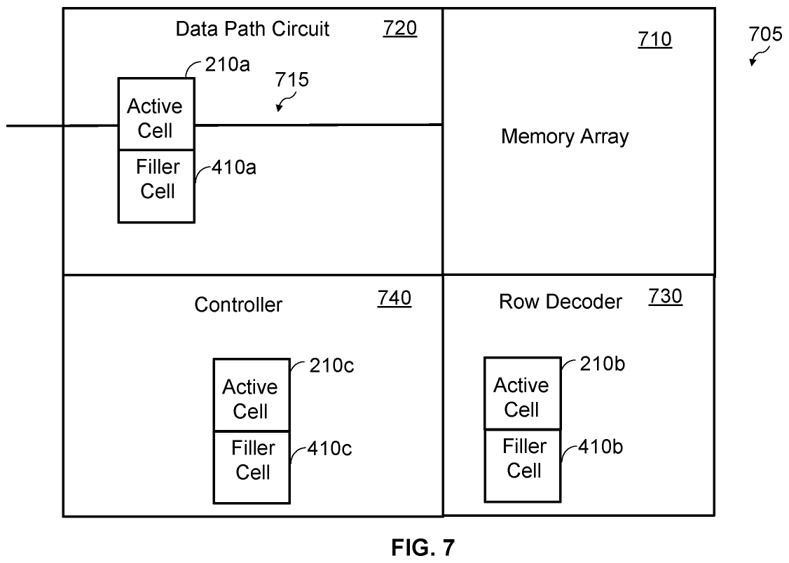

FIG. 7 is a block diagram illustrating an exemplary memory system 705 in which aspects of the present disclosure may be used. In this example, the memory system 705 includes a memory array 710, a data path circuit 720, a row decoder 730, and a controller 740. The memory array 710 (e.g., synchronous dynamic random access memory (SDRAM) array) includes an array of memory cells where each memory cell may be configured to store a bit. The memory system 705 may be integrated on the chip 100.

The data path circuit 720 includes data paths that carry data (e.g., data bits) to be written to the memory array 710, and/or carry data read from the memory array 710. The data may come from a processor (not shown) or another circuit that is coupled to the data path circuit 720 and uses the memory array 710 to store data. The data path circuit 720 may include circuitry for writing data to and reading data from the memory array 710 including, for example, a pre-charge circuit, sense amplifiers, drivers, and the like.

The row decoder 730 is configured to select a row of memory cells in the memory array 710 for writing or reading data under the control of the controller 740. The controller 740 is configured to control operations of the memory system 705 including, for example, read operations, write operations, retention operations, and the like. The controller 740 may also be referred to as logic or another term.

The filler cell 410 according to aspects of the present disclosure may be used to reduce IR drops in the memory system 705. In this regard, FIG. 7 illustrates multiple filler cells 410a, 410b, and 410c that may be placed at various locations in the memory system 705 to reduce IR drops, where each of the filler cells 410a, 410b, and 410 may be a instance of the filler cell 410. In this example, each of the filler cells 410a, 410b, and 410c is placed next to a respective active cell 210a, 210b, and 210c in the layout of the memory system 705 to reduce IR drops for the respective active cell 210a, 210b, and 210c. It is to be appreciated that the filler cells 410a, 410b, and 410c and the active cells 210a, 210b, and 210c are greatly enlarged in FIG. 7 for ease of illustration.

FIG. 7 shows an example of one of the active cells 210a and the respective filler cell 410a in the data path circuit 720. The active cell 210a may be a driver cell coupled to the memory array 710 through the data path 715 coupled between the active cell 210a and the memory array 710. For example, the data path 715 may be coupled to the output (e.g., metal path 598) of the active cell 210a for a write data path and coupled to the input (e.g., metal path 596) of the active cell 210a for a read data path. Although one active cell 210a is shown in FIG. 7 for simplicity, it is to be appreciated that the data path circuit 720 may include multiple active cells (e.g., driver cells) driving multiple data paths, and multiple instances of the filler cell 410 placed next to the active cells.

FIG. 7 also shows an example of one of the active cells 210b and the respective filler cell 410b in the controller 740, and one of the active cells 210c and the respective filler cell 410c in the row decoder 730 to illustrate that filler cells according to aspects of the present disclosure may also be placed in the controller 740 and/or the row decoder 730 to reduce IR drops in the controller 740 and/or the row decoder 730.

In certain aspects, the layout of the memory system 705 may include areas reserved for filler cells (e.g., to implement a potential future engineering change order (ECO) and/or another purpose). In these aspects, instances of the filler cell 410 may be placed in one or more of these areas to reduce IR drops. For example, the processor 620 may identify one or more areas in the layout of the memory system 705 or another system reserved for filler cells, and place one or more instances of the filler cell 410 in the one or more areas to reduce IR drops.

The transistor 540 and the dummy device 565 may be implemented using a FinFET process, a gate-all-around (GAA) FET process, a planar FET process, or another type of process. For the example of a FinFET process, each of the OD regions 510 and 520 includes fins extending in the first direction 512 in which each gate 516-1 to 516-4 and 518-1 to 518-4 may surround each fin on three sides. For the example of a GAA FET process, each of the OD regions 510 and 520 includes channels (e.g., nanosheets) in which each gate 516-1 to 516-4 and 518-1 to 518-4 may surround each channel on four sides.

Implementation examples are described in the following numbered clauses:
1. A chip, comprising:
   a first cell comprising:
      a first diffusion region extending in a first direction; and
      first gates formed over the first diffusion region, wherein each of the first gates is elongated and extends in a second direction perpendicular to the first direction;
   a second cell comprising:
      a second diffusion region extending in the first direction; and
      second gates formed over the second diffusion region, wherein each of the second gates is elongated and extends in the second direction;
   a first contact extending in the second direction over the first diffusion region and the second diffusion region, wherein the first cell comprises a first portion of the first contact and the second cell comprises a second portion of the first contact;
   a first via disposed on the first contact between the first diffusion region and the second diffusion region, and
   a rail extending in the first direction over the first via, wherein the first via couples the first contact to the rail.
2. The chip of clause 1, further comprising:
   a second via disposed on the second portion of the first contact;
   a first metal path extending in the first direction over the second via, wherein the second via couples the first contact to the first metal path; and
   second metal path extending in the second direction over the first metal path and the rail, wherein the second metal path is coupled to the first metal path and the rail.
3. The chip of clause 2, wherein:
   the first metal path and the rail are formed from a first metal layer; and
   the second metal path is formed from a second metal layer above the first metal layer.
4. The chip of clause 2 or 3, further comprising:
   a third via disposed on the first portion of the first contact; and
   a third metal path extending in the first direction over the third via, wherein the third via couples the first contact to the third metal path.
5. The chip of clause 4, wherein the second metal path extends over the third metal path and is coupled to the third metal path.
6. The chip of clause 5, wherein:
   the first metal path, the third metal path, and the rail are formed from a first metal layer; and
   the second metal path is formed from a second metal layer above the first metal layer.
7. The chip of clause 4, further comprising a fourth metal path extending in the second direction over the third metal path and the rail, wherein the fourth metal path is coupled to the third metal path and the rail.
8. The chip of clause 7, wherein:
   the first metal path, the third metal path, and the rail are formed from a first metal layer; and
   the second metal path and the fourth metal path are formed from a second metal layer above the first metal layer.
9. The chip of any one of clauses 2 to 8, wherein the second cell further comprises:
   a second contact extending in the second direction over the second diffusion region; and
   a third contact disposed extending in the second direction over the second diffusion region.
10. The chip of clause 9, further comprising:
   a third via coupling the second contact to the first metal path; and
   a fourth via coupling the third contact to the first metal path.
11. The chip of clause 10, wherein a first one of the second gates is between the first contact and the second contact, and a second one of the second gates is between the second contact and the third contact.
12. The chip of clause 11, wherein the second diffusion region is a n-type diffusion region and the gates are coupled to a supply voltage.
13. The chip of clause 12, wherein the rail comprises a ground rail.
14. The chip of clause 11, wherein the second diffusion region is a p-type diffusion region and the second gates are coupled to a ground potential.
15. The chip of clause 14, wherein the rail comprises a voltage supply rail.
16. The chip of any one of clauses 2 to 15, wherein the first cell further comprises:
   a second contact extending in the second direction over the first diffusion region; and
   a third contact disposed extending in the second direction over the first diffusion region.
17. The chip of clause 16, wherein:
   the first gates are coupled to an input of the first cell; and
   the second contact and the third contact are coupled to an output of the first cell.
18. The chip of clause 17, further comprising a data path coupled to the output of the first cell.
19. The chip of clause 18, further comprising a memory array, wherein the data path is coupled between the output of the first cell and the memory array.
20. The chip of clause 17, further comprising a data path coupled to the input of the first cell.
21. The chip of clause 20, further comprising a memory array, wherein the data path is coupled between the input of the first cell and the memory array.
22. The chip of any one of clauses 1 to 11 and 16 to 20, wherein the first diffusion region is a n-type diffusion region and the rail is a ground rail.
23. The chip of any one of clauses 1 to 11 and 16 to 20, wherein the first diffusion region is a p-type diffusion region and the rail is a voltage supply rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first cell comprising:
a first diffusion region extending in a first direction; and
first gates formed over the first diffusion region, wherein each of the first gates is elongated and extends in a second direction perpendicular to the first direction;
a second cell comprising:
a second diffusion region extending in the first direction; and
second gates formed over the second diffusion region, wherein each of the second gates is elongated and extends in the second direction;
a first contact extending in the second direction over the first diffusion region and the second diffusion region, wherein the first cell comprises a first portion of the first contact and the second cell comprises a second portion of the first contact;
a first via disposed on the first contact between the first diffusion region and the second diffusion region, and
a rail extending in the first direction over the first via, wherein the first via couples the first contact to the rail.

2. The chip of claim 1, further comprising:
a second via disposed on the second portion of the first contact;
a first metal path extending in the first direction over the second via, wherein the second via couples the first contact to the first metal path; and
second metal path extending in the second direction over the first metal path and the rail, wherein the second metal path is coupled to the first metal path and the rail.

3. The chip of claim 2, wherein:
the first metal path and the rail are formed from a first metal layer; and
the second metal path is formed from a second metal layer above the first metal layer.

4. The chip of claim 2, further comprising:
a third via disposed on the first portion of the first contact; and
a third metal path extending in the first direction over the third via, wherein the third via couples the first contact to the third metal path.

5. The chip of claim 4, wherein the second metal path extends over the third metal path and is coupled to the third metal path.

6. The chip of claim 5, wherein:
the first metal path, the third metal path, and the rail are formed from a first metal layer; and
the second metal path is formed from a second metal layer above the first metal layer.

7. The chip of claim 4, further comprising a fourth metal path extending in the second direction over the third metal path and the rail, wherein the fourth metal path is coupled to the third metal path and the rail.

8. The chip of claim 7, wherein:
the first metal path, the third metal path, and the rail are formed from a first metal layer; and
the second metal path and the fourth metal path are formed from a second metal layer above the first metal layer.

9. The chip of claim 2, wherein the second cell further comprises:
a second contact extending in the second direction over the second diffusion region; and
a third contact disposed extending in the second direction over the second diffusion region.

10. The chip of claim 9, further comprising:
a third via coupling the second contact to the first metal path; and
a fourth via coupling the third contact to the first metal path.

11. The chip of claim 10, wherein a first one of the second gates is between the first contact and the second contact, and a second one of the second gates is between the second contact and the third contact.

12. The chip of claim 11, wherein the second diffusion region is a n-type diffusion region and the gates are coupled to a supply voltage.

13. The chip of claim 12, wherein the rail comprises a ground rail.

14. The chip of claim 11, wherein the second diffusion region is a p-type diffusion region and the second gates are coupled to a ground potential.

15. The chip of claim 14, wherein the rail comprises a voltage supply rail.

16. The chip of claim 2, wherein the first cell further comprises:
a second contact extending in the second direction over the first diffusion region; and
a third contact disposed extending in the second direction over the first diffusion region.

17. The chip of claim 16, wherein:
the first gates are coupled to an input of the first cell; and
the second contact and the third contact are coupled to an output of the first cell.

18. The chip of claim 17, further comprising a data path coupled to the output of the first cell.

19. The chip of claim 18, further comprising a memory array, wherein the data path is coupled between the output of the first cell and the memory array.

20. The chip of claim 17, further comprising a data path coupled to the input of the first cell.

21. The chip of claim 20, further comprising a memory array, wherein the data path is coupled between the input of the first cell and the memory array.

22. The chip of claim 1, wherein the first diffusion region is a n-type diffusion region and the rail is a ground rail.

23. The chip of claim 1, wherein the first diffusion region is a p-type diffusion region and the rail is a voltage supply rail.
